(19) United States
(12) Patent Application Publication
(10) Pub. No.: US 2020/0052215 A1
(43) Pub. Date: Feb. 13, 2020

(54) CURABLE COMPOSITION AND ITS USE FOR ELECTRIC DEVICE

(71) Applicant: Henkel AG & Co. KGaA, Duesseldorf (DE)

(72) Inventor: Jing Zhou, Shanghai (CN)

(21) Appl. No.: 16/660,169

(22) Filed: Oct. 22, 2019

Related U.S. Application Data
(62) Division of application No. 15/044,195, filed on Feb. 16, 2016.
Application No. 15/044,195 is a continuation of application No. PCT/CN2013/082355, filed on Aug. 27, 2013.

(51) Int. Cl. H01L 51/00; H01L 51/56; C08G 65/18; C08G 59/40

(52) U.S. Cl. CPC H01L 51/0034; H01L 51/56; H01L 51/5253; C08G 59/4007; C08G 59/40; C08G 65/18

(57) ABSTRACT

The present invention relates to a curable composition for the sealing, encapsulation, or laminating of electronic devices. The curable compositions according to the invention include those having an aliphatic epoxy resin, an aliphatic oxetane resin and a thermal cure initiator, wherein the compositions provide excellent transparency and good moisture barrier property after cure.

### FIELD OF THE INVENTION

The present invention relates to a thermally curable composition, which comprises an aliphatic epoxy compound, an aliphatic oxetane compound and a thermal cure initiator. The invention further relates to an electronic device comprising a cured material obtained from said curable composition. The curable composition is particularly suitable as a laminating adhesive, encapsulant or sealant for OLED (organic light-emitting diodes) devices.

### BACKGROUND

Novel display technologies, such as OLEDs, offer many advantages compared with LCDs (liquid crystal displays). The LCD devices are not self-emitting devices, so that they have limitations in brightness, contrast and viewing angle. On the other hand, the OLED display devices are self-emitting devices, so that they have a wide viewing angle, high contrast and low power consumption. Especially, they are light-weight and thin because they do not need a backlight. Moreover, the OLED display devices can be used in wide range of temperature and fabricated by a simple process since they are solid. However, these organic thin films are very vulnerable to moisture and oxygen. The oxidation causes the degradation of the organic thin films which induces the “dark spots”. Thus, the organic thin films should be encapsulated to prevent invasion of moisture and oxygen.

A conventional structure is, for example, encapsulation between two glass plates. The OLED layer structure is produced on a first substrate, and a cover glass is bonded to this substrate with the aid of an adhesive, which is applied along the edge of the OLED structure. This type of encapsulation is referred to “Encap glass type”. In this configuration, both glass substrate and the glass lid are impermeable to oxygen and moisture, and the sealant is the only material that surrounds the device with any appreciable permeability. For optoelectronic devices, moisture permeability is very often more critical than oxygen permeability; consequently, the moisture barrier properties of the edge sealant is critical to the successful performance of the device.

Curable compositions for edge sealing of “Encap glass type” OLED devices are e.g. disclosed in U.S. Pat. No. 7,902,305 B2. The curable composition disclosed therein consists of an oxetane compound and a cationic initiator, wherein said compositions provide low moisture permeability and good adhesive strength. However, the compositions do not need to be transparent because of the edge seal application.

The “Encap glass type” has some limits in terms of rigidity, thickness and small size. A popular design at present is to apply the adhesive to the entire surface of the OLED substrate, which is known as “full area encapsulation”. Full area encapsulation has the advantage that the substrate and cover form a very strong mechanical unit and are superior to edge-encapsulated compounds. In this case, much larger units can be achieved with full-area encapsulated compounds.

More popular OLEDs are designed with transparent cathodes in such a way that the light generated exits through the cathode, named as “top emission OLED”. Top emission OLED is especially suitable for Active-matrix OLEDs (AMOLED) for higher resolution and larger display sizes. AMOLED require a thin-film transistor (TFT) backplane to switch each individual pixel on or off. If using a bottom emission OLED, the aperture ratio would be limited because the TFTs occupy a certain area. On the other hand, top-emission OLED uses a reflective anode to optically isolate the TFTs and OLEDs.

A top emission OLED requires that all the layers above the OLED layer, including the adhesive layer, are transparent and remain non-yellowing after being exposed to elevated temperatures with humidity. However, as the OLED materials have the intrinsic problem that they are vulnerable to UV light, the radiation cure of such adhesive e.g. with an UV light cure method cannot be applied directly to an OLED if there is no protection against UV on top of it. Considering thermal sensitivity of OLED as well, a low temperature heat cure method is a preferred option by OLED device manufacturers.

A number of attempts have been made to prepare good water barrier adhesives/sealants for OLED devices. For example, US 20040225025 A1 discloses curable compositions comprising an epoxy resin and a hydroxyl-functional compound, wherein said composition can provide good barrier properties but does not remain transparent after being exposed to elevated temperatures.

Another patent application WO 2012/045588 A1 discloses a radiation curable composition comprising at least one radiation-curable resin, at least one specific anti-oxidant and at least one photo initiator salt, which can be cured into a material with low water vapor transmission rate, good adhesion and that remains transparent over a long period of time. However, this radiation cure method can not be used in top emission type AMOLED as explained above.

In many configurations, both the glass substrate and the cover material are essentially impermeable to oxygen and moisture, and the sealant is the only material that surrounds the device with any appreciable permeability. Good barrier sealants will exhibit low bulk moisture permeability, good adhesion, and strong interfacial adhesive/substrate interactions. If the quality of the adhesion of substrate to sealant interface is poor, the interface may function as a weak boundary, which allows rapid moisture ingress into the device regardless of the bulk moisture permeability of the sealant. If the interface is at least as blocking as the bulk sealant, then the permeation of moisture typically will be dominated by the bulk moisture permeability of the sealant itself.

Notwithstanding the state of technology it is desirable to provide heat curable corn-positions suitable as adhesives/coatings for OLED devices which, after cure, have a good transparency, good moisture barrier property, and do not show yellowing at normal or elevated temperatures. Also the adhesion to the substrate shall be excellent.

Hence it is an objective of the present invention to provide heat curable compositions for the sealing, encapsulation, or laminating of an OLED device, wherein the cured product exhibits good transparency, low water permeability, and remains transparent even upon contact with humidity under elevated temperatures.

### DETAILED DESCRIPTION OF THE INVENTION

These objectives are solved by curable compositions comprising a mixture of defined epoxy and defined oxetane compounds as well as a thermal cure initiator.

Hence, a first object of the present invention is a curable composition comprising
a) an aliphatic epoxy compound,
b) an aliphatic oxetane compound, and
c) a thermal cure initiator.

Another object of the invention is an electronic device comprising a substrate, a layer of OLEDs on this substrate, an adhesive layer on the OLED and the substrate and optionally a second substrate (cover) on top of the adhesive layer, wherein the adhesive layer is a cured composition obtained by curing the curable composition according to the invention.

The materials selected for the substrate and cover will depend upon the end use application, and include inorganic materials, metals including metal alloys, ceramics, polymers and composite layers. Inorganic materials such as glass provide good barrier properties against water, oxygen and other harmful species and also provide a substrate upon which electronic circuitry can be built. Where flexibility is desired and transparency is not needed, metal foils can be used. Ceramics also provide low permeability, and they provide transparency as well in some cases. Polymers are often preferred where optical transparency is desired and flexibility is desired. Preferred low permeability polymers include polyesters, such as polyethylene terephthalate (PET) and polyethylene napthalate (PEN), polyethersulfones, polyimides, polycarbonates and fluorocarbons, with such layers commonly being used in connection with composite substrates or covers. As second substrate preferably optical transparent materials are applied, e.g. polymeric substrates or glass.

For a top emission OLED or a transparent OLED encapsulated by an adhesive layer, the adhesive layer should be optically transparent to ensure the light transmitting through the adhesive layer and the substrate. Herein, transparent is defined as having a transmittance of higher than 85%, preferably higher than 90% within the visible light spectrum range (400-800 nm). Additional requirement for the adhesive layer is that it should stay transparent and non-yellowing after heat and humidity aging. A transparent but yellowing material can exhibit a high transmittance of 90% at long wavelength (600-800 nm), but has low transmittance of less than 80% at short wavelength (400-500 nm). This will have a negative effect on the OLED display quality especially for a full-color OLED display which needs consistent transmittance for the whole visible light wavelength range. Herein, transparent and non-yellowing is defined as having a transmittance of higher than 85% at a wavelength of 400 nm.

To achieve good transparency and non-yellowing properties, an aliphatic epoxy compound is used in the composition. The term “an aliphatic epoxy compound” as used in this specification does encompass the presence of two or more aliphatic epoxy compounds. Aliphatic epoxy compounds are typically formed by glycidylation of aliphatic alcohols or polyols. The resulting compounds may be monofunctional (e.g. dodecanol glycidyl ether), difunctional (butanediol diglycidyl ether), or of higher functionality (e.g. trimethylolpropane triglycidyl ether). “Aliphatic” means there is no unsaturated bond, such as aromatic groups or C═C bonds in the backbone of the epoxy resin. It is known that aromatic groups or C═C bonds can easily cause yellowing of the cured material, due to the oxidation of these unsaturated bonds during heat cure or during storage at elevated temperatures.

In one embodiment of the present invention the aliphatic epoxy compound is selected from aliphatic epoxy resins. Suitable aliphatic epoxy compounds include, but are not limited to, aliphatic glycidyl ethers, aliphatic glycidyl esters, cycloaliphatic glycidyl ethers, cycloaliphatic glycidyl esters, cycloaliphatic epoxy resins and combinations or mixtures thereof.

Representative aliphatic glycidyl ethers are for example commercially available from Hexion and include 1,4-butanediol-diglycidylether (Heloxy 67), 1,6-hexanediol-diglycidylether (Heloxy modifier HD), trimethyolpropane-triglycidylether (Heloxy 48), neopentylglycol-diglycidylether (Heloxy 68), alkyl C12-14 glycidylether (Heloxy 8), butyl-glycidylether (Heloxy 61), and 2-ethylhexyl-glycidylether (Heloxy 116).

Representative cycloaliphatic glycidyl ethers include hydrogenated bisphenol A diglycidyl ethers (for example sold under the trade name Epalloy 5000 and Epalloy 5001 from CVC Specialty Chemicals; or YX8000 from Japanese Epoxy Resins Co. Ltd.), hydrogenated polybisphenol A diglycidyl ethers (for example sold under the trade name YX8034 from Japanese Epoxy Resins Co. Ltd.), solid hydrogenated polybisphenol A diglycidyl ethers (for example sold under the trade name YX8040 from Japanese Epoxy Resins Co. Ltd.), cyclohexanedimethylol diglycidylether (for example sold under the trade name Heloxy 107 from Hexion), tricyclodecane dimethanol diglycidylether (for example sold under the trade name EP4088S from Adeka).

Representative cycloaliphatic epoxy resins include 3,4 epoxycyclohexylmethyl 3′,4′-epoxycyclohexane carboxylate (for example sold under the trade name UVA Cure 1500 from Cytec; or UVR-6105, UVR-6107 and UVR-6110 from Dow), bis-(3,4-epoxycyclohexylmethyl)adipate (for example sold under the trade name UVR-6128 from Dow), 3,4-epoxycyclohexanemethyl 3′,4′-epoxycyclohexylcarboxylate modified ε-caprolactones (available in various molecular weights for example as Celloxide 2081, Celloxide 2083, Celloxide 2085, Epolead GT 302 and Epolead GT 403 from Daicel), limonene dioxide.

Representative aliphatic and cycloaliphatic glycidyl esters include glycidyl ester of neodecanoic acid (for example sold under the trade name Erisys GS-110 from CVC Specialty Chemicals or Cardura E10P from Hexion), glycidyl ester of linoleic acid dimer (for example sold under the trade name Erisys GS-120 from CVC Specialty Chemicals), dimer acid diglycidyl ester (for example sold under the trade name Heloxy Modifier 71 from Hexion), diglycidyl 1,2-cyclohexanedicarboxylate (for example sold under the trade name Epalloy 5200 from CVC Specialty Chemicals).

The aliphatic epoxy compound can be liquid or solid at ambient temperature (25° C.). It can comprise monomeric, oligomeric or polymeric compounds. The functionality of the epoxy compounds is preferably from 1 to 4, but a mean functionality of about 2 (1.9 to 2.1, preferably 2.0) is preferred. At least one aliphatic epoxy resin or mixtures of different aliphatic epoxy resins can be used. The total amount of aliphatic epoxy resin is preferably 35 to 97.9 wt-%, more preferably 50 to 92 wt-%, and most preferably 60 to 90 wt-%, each based on the total weight of the curable composition of the present invention.

The composition further comprises an aliphatic oxetane compound, i.e. an aliphatic compound containing at least one oxetane group. The term “an aliphatic oxetane compound” as used in this specification does encompass the presence of two or more aliphatic oxetane compounds. In suitable aliphatic compounds, carbon atoms can be joined together in straight chains, branched chains, or non-aromatic rings (in which case they are called alicyclic). Preferably this compound contains 1 or 2 oxetane groups per molecule. Preferably up to two reactive oxetane groups are bound to a backbone. Preferably the aliphatic oxetane compound is essentially free of epoxy groups, i.e. comprises on average less that 0.01 epoxy groups per oxetane group in the compound, more preferred the aliphatic oxetane compound is free of epoxy groups. The oxethane group may include further substituents, for example one or more alkyl groups, which may include also hetero atoms, like O, S, N, and halogen as ether, ester group or the like. As alkyl substituents linear, branched or alicyclic groups can be selected. The alkyl substituents may comprise independently from 1 to 12 C-atoms. Such substituents may include for example alkyl as methyl, ethyl, propyl, butyl, hexyl; alkoxy, like methoxy, ethoxy, butoxy; polyether structures; ester groups or the like. Preferably the aliphatic oxetane compound has a molecular weight of less than 500 g/mol. Preferably the oxetane compound is liquid at room temperature (25° C.). Preferably the viscosity of the liquid aliphatic oxetane is about 1 mPas to 500 mPas at 25° C. In one embodiment the aliphatic oxetane compound shall include alkyl ether substituents or bridges.

Preferably the aliphatic oxetane compound has the structure as below:

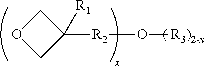

wherein R₁ is selected from the group consisting of hydrogen, C1 to C12 alkyl, C1 to C12 haloalkyl, C1 to C12 alkoxy and C1 to C12 alkyloyl groups; R₂ is selected from C1 to C12 alkylene groups; R₃ is selected from hydrogen, linear C1 to C12 alkyl, branched C3 to C12 alkyl and C5 to C12 cycloalkyl groups, and x is an integer from 1 to 2.

When x is 1, the above structure contains only one oxetane group. Exemplary examples include, but are not limited to

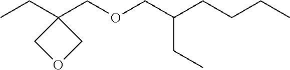 [SMILES: CCCCC(CC)COCC1(CC)COC1]

When x is 2, there is no R₃ group, which means that two oxetane groups are connected by R₂ groups linked with oxygen. Exemplary embodiments include, but are not limited to

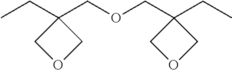

Representative commercially available aliphatic oxetane resins include 3-ethyl-3-[(2-ethylhexyloxy)methyl] oxetane, 3-ethyl-3-{[(3-ethyl oxetane-3-yl)methoxy]methyl}oxetane, 3-ethyl-3-hydroxymethyloxetane, 3-ethyl-3-cyclohexyloxymethyloxetane.

The aliphatic oxetane compounds are excellent in cationic polymerizability, which is better than that of glycidyl ethers or glycidyl esters. Also the water barrier properties of the cured composition are improved by adding an aliphatic oxetane compound.

Liquid oxetanes are preferred. Preferably, aromatic groups containing oxetane compound are excluded from compositions according to the present invention, since the presence of such compounds results in an increased yellowing effect of the cured composition, for example when used as adhesive layer.

The total amount of aliphatic oxetane compound is preferably 2 to 50 wt-%, more preferably 4 to 40 wt-%, and most preferably 6 to 35 wt-%, each based on the total weight of the curable composition of the present invention.

It is advantageous to use combinations of aliphatic epoxy compounds and aliphatic oxetane compounds in the heat curable compositions of the present invention because said mixtures exhibit a reduced curing time, improved water barrier property and a good processing viscosity.

In the present invention, a thermal cure initiator is used for the crosslinking reaction. Hence, the composition according to the invention further comprises a thermal cure initiator. The term “a thermal cure initiator” as used in this specification does encompass the presence of two or more aliphatic thermal cure initiators.

As thermal cure initiator the curable compositions of the invention preferably include one or more cationic initiators. As cationic initiators Brønsted acids, Lewis acids and their derivatives involving various latent initiators are widely used. The Brønsted acids are proton (H+ ion) donors, which are generally neutral or cationic. The Lewis acids are electron pair acceptors. The initiator can for example be selected from Lewis acids like metallic salts from halogene e.g. boron trifluoride, tin (IV) chloride and sulfonyl chloride. Also, typical Brønsted acids can be used, e.g. sulfuric acid, phosphoric acid, trifluor acetic acid, or other strong acids.

Exemplary thermal cure initiators include Brønsted acids, Lewis acids, and latent thermal acid generators. Examples of latent thermal acid generators include, but are not limited to, diaryliodonium salts, benzylsulfonium salts, phenacylsulfonium salts, N-benzylpyridinium salts, N-benzylpyrazinium salts, N-benzylammonium salts, phosphonium salts, hydrazinium salts, ammonium borate salts, etc.

The thermal cure initiator is used preferably in an total amount of 0.1 to 5 wt-%, more preferably 0.2 to 3 wt-%, particularly preferably 0.5 to 2 wt-%, and most preferably 0.5 to 1 wt-%, each based on the total amount of the curable composition of the present invention.

A composition according to the present invention may further comprise one or more additives, preferably selected from adhesion promoters, antioxidants, tackifiers, plasticizer, rheology modifiers, like thixotropic agents, or nanofillers. Preferably, such additives are selected in a way and employed in amounts that they do not adversely influence the transparency of the cured composition. The additives are preferably used in a total amount of from 0 to 10 wt-% based on the total weight of the curable composition of the present invention.

Preferably, the curable composition according to the invention shows after crosslinking an initial transmittance at 400 nm wavelength of at least 85%, preferably at least 90%, more preferred at least 92%. It is further preferred, that also the transmittance at 400 nm wavelength after aging at 85° C. and 85% relative humidity for ten days is at least 85%, preferably at least 90%, more preferred at least 91.5%. The initial transmittance and the transmittance after aging are measured as outlined in the examples part of this specification under the heading transparency.

The main feature of the curable composition according to the invention allowing achieving the desired transmittance is the combination of an epoxy compound and an oxetane compound, wherein both compounds have to be aliphatic. Moreover, the weight ratio of epoxy compound and oxetane compound has to be selected appropriately. Guidance therefore can be found in the examples and the specification of the preferred and particularly preferred amounts of each of these components as outlined above. Moreover, as already mentioned above the amount and kind of additives shall be selected to not deteriorate transparency. Preferably, the total amount of additives is at most 10 wt-% based on the total weight of the curable composition.

Hence, in one preferred embodiment of the present invention the curable composition comprises:
a) from 35 to 97.9 wt-% of the aliphatic epoxy compound,
b) from 2 to 50 wt-% of the aliphatic oxetane compound,
c) from 0.1 to 5 wt-% of the thermal cure initiator,
d) from 0 to 10 wt-%, preferably from 0 to 5 wt-%, of one or more additives, wherein the amount of all components a) to d) sums up to 100 wt-%.

Preferably, the curable composition according to the invention is liquid or viscous and has a viscosity of 50 to 50,000 mPas, preferably from 500 to 10,000 mPas at 25° C.

The present curable composition of the present invention is suitable in preparation of electronic devices which comprise at least a substrate, a light emitting component, and a layer of a cured material derived from curing the curable composition according to the invention, wherein said layer is transparent, i.e. has an initial transmittance of at least 85% at 400 nm wavelength.

Further examples of the electronic device in which the present curable composition may be used include OLED devices. The present curable compositions are particularly suitable as encapsulants, adhesives or sealants for OLEDs to protect the organic light emitting layer and/or the electrodes in the OLEDs from oxygen and/or water.

A further aspect of the present invention is an OLED device containing a layer of a cured composition according to the invention. The OLED device architecture may have two main structures: one is bottom or top emission. Bottom emission devices use a transparent or semi-transparent bottom electrode to get the light through a transparent substrate. Top emission devices use a transparent or semi-transparent top electrode emitting light directly. The other is transparent OLEDs. Transparent OLEDs use transparent or semi-transparent contacts on both sides of the device to create displays that can be made to be both top and bottom emitting (transparent). Such device includes a substrate, the OLED stack, the adhesive layer and a second substrate. The adhesive layer is applied and cured by thermal crosslinking. The present curable composition can be applied in all such structures.

A further aspect of the present invention is a method of making an electronic device comprising the steps:
providing a substrate having on one side at least an electronic circuit,
applying on such side a layer of a composition of the invention,
optionally bonding a second substrate on the layer,
curing the composition by heating up to a temperature of 80-120° C.

A further object of the invention is an electronic device comprising at least a substrate, a light emitting compound, and a layer of the cured composition according to the invention, wherein the layer of the cured composition has an initial transmittance of at least 85% at 400 nm wavelength.

A further aspect of the present invention is a method of making an organic light emitting diode (OLED) device comprising the steps:
providing a substrate having bound on one side OLED stacks,
applying on the OLED surface a layer of a composition of the invention,
optionally bonding a second transparent substrate on the layer,
curing the composition by heating up to a temperature of 80-120° C.

In a typical application process, the curable composition is mixed and applied to an OLED device, cured by heating to 80-120° C., preferably 90-100° C., over a curing time of 30-90 min, preferably over a curing time of 30-60 min.

The laminating adhesive preferably is a clear liquid, and may be applied by coating or printing, for example, by curtain coating, spray coating, roll coating, slit coating, stencil printing, screen printing, and other coating and printing methods known in the art. The viscosity of the composition can be selected according to the application method.

The adhesive according to the invention comprises a reactive aliphatic oxetane compound and an aliphatic epoxy compound. The mixture will react during the thermal curing process to form a transparent adhesive layer. The cured adhesive film shows an excellent bonding to the substrates and has an improved stability against light emitted from the OLED device. The barrier property against water is improved.

Water can damage the organic materials in the display device. Therefore, improved sealing processes are important for practical manufacturing. Water damage may especially limit the longtime stability of such devices. It is a particular advantage of the electronic device of the present invention that the electronic device exhibits a low water vapor transmission rate and/or remains transparent over a long period of time without showing any significant yellowing.

Another aspect of the invention is the use of the curable composition as a laminating adhesive, encapsulant or sealant for an OLED device. Yet another aspect of the invention is the use of the curable composition as a vapor barrier sealant, and/or edge sealant for electronic devices or optoelectronic devices.

### Examples

Ingredients used in the curable compositions according to the invention and comparative formulations are set forth in the following Table (Table 1)

TABLE 1

| Name | Description |
|---|---|
| Aliphatic epoxy | YX8000 from Japanese epoxy resin Co. Ltd. |
| resin 1 | (Hydrogenated bisphenol A diglycidyl ether) |
| Aliphatic epoxy | YX8034 from Japanese epoxy resin Co. Ltd. |
| resin 2 | (Hydrogenated bisphenol A diglycidyl ether) |
| Aliphatic epoxy | Celloxide 2021P from Daicel |
| resin 3 | ((3′,4′-epoxycyclohexane) methyl- |
| | 3,4,-epoxycyclohexane carboxylate) |
| Epiclon EXA- | from Dainippon Ink and Chemicals Inc. |
| 835LV | (Bisphenol F diglycidyl ether) |
| Oxt 212 | 3-ethyl-3-[(2-ethylhexyloxy)methyl]oxetane |
| | from Toagosei |
| Oxt 221 | 3-ethyl-3-{[(3-ethyl |
| | oxetane-3-yl)methoxy]methyl}oxetane |
| | from Toagosei |
| CXC-1612 | antimony hexafluoride based catalyst |
| | from King industries |
| SILQUEST A 187 | Glycidoxypropyltrimethoxysilane from Momentive |
| | (Adhesion promoter) |

Structure of YX8000 (n=0.5 on average) and YX8034 (n=1 on average)

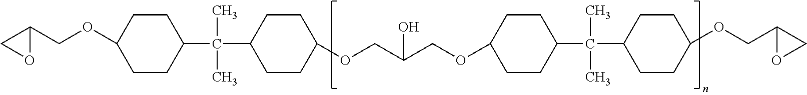

### Structure of Celloxide 2021P

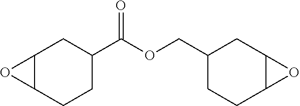 [SMILES: O=C(OCC1CCC2OC2C1)C1CCC2OC2C1]

### Structure of Oxt 212:

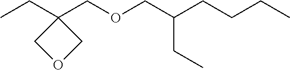 [SMILES: CCCCC(CC)COCC1(CC)COC1]

### Structure of Oxt 221:

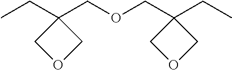

Compositions of examples and comparative examples are listed in Table 2. The given amounts of the components are parts by weight. In a typical process, the compositions are prepared by mixing all the compounds, the mixture is cured at 100° C. for 30 min and the properties of the resulting cured material are tested. The water vapor transmission rate (WVTR) and the transparency of the cured products are determined according to the following test methods.

### Water Vapor Transmission Rate (WVTR)

A cured film of the respective composition is used to measure the WVTR using a Mocon Permatran—W model 3/33 instrument. Measurement parameters are: 50° C., 100% relative humidity and 1013 mbar. The typical thickness of the cured films ranges from 150 to 250 micron. The values given in Tables 2 are equilibrated values and are normalized to a film thickness of 1 mm using units of g/m²·day.

### Transparency

Two transparent glass plates (each of 1 mm thickness) are attached parallel to each other in a spaced apart relationship by using two stripes of a pressure sensitive adhesive (200 micron thickness). The cavity defined by the two glass plates and the pressure sensitive adhesive stripes is filled with the mixed composition. The curable composition is then cured at 100° C. for 30 min to form a cured film between the two glass plates. The initial transmittance is determined by passing a light beam of 400 nm wavelength in an orthogonal direction through the glass/cured film/glass assembly, using a UV/Vis spectrophotometer (Lambda 35). The measurement is repeated after exposing the glass/cured film/glass assembly to 85° C./85% relative humidity (85RH) for 10 days. The values are given in Table 2.

TABLE 2

| | Ex. 1 | Ex. 2 | Ex. 3 | Ex. 4 | Comp. 1 | Comp. 2 |
|---|---|---|---|---|---|---|
| Aliphatic epoxy resin 1 | 90 | 80 | | | | |
| (YX8000) | | | | | | |
| Aliphatic epoxy resin 2 | | | 80 | 70 | | 70 |
| (YX8034) | | | | | | |
| Aliphatic epoxy resin 3 | | 10 | | | | 30 |
| (Celloxide 2021P) | | | | | | |
| Epiclon EXA-835LV | | | | | 90 | |
| Oxt 212 | 10 | 10 | 20 | | 10 | |
| Oxt 221 | | | | 30 | | |
| CXC-1612 | 1 | 1 | 1 | 0.5 | 1 | 1 |
| SILQUEST A 187 | 1 | 1 | 1 | 1 | 1 | 1 |
| Water Vapor | 4.0 | 5.1 | 4.8 | 3.1 | 8.8 | 8.1 |
| Transmission rate | | | | | | |
| [g/m2 · day] | | | | | | |
| Initial Transmittance | 92.6% | 92.4% | 93.1% | 93.5% | 92.1% | 92.5% |
| @400 nm | | | | | | |
| Transmittance after 10 | 92.1% | 91.7% | 92.8% | 93.0% | 78.4% | 91.5% |
| days @85° C./85RH | | | | | | |
| @400 nm | | | | | | |

It is obvious from the results given in table 2 for the examples according to the invention (Ex. 1-4), that by using a mixture of an aliphatic resin and an aliphatic oxetane, very low water vapor permeability can be obtained. Moreover, the cured products exhibited very good transparency with an initial transmittance of over 92%, and even maintained good transparency after storage at 85° C./85RH for 10 days. For different oxetanes, it can be seen from example 4 that OXT 221 resulted in the lowest WVTR data, which could be due to the higher crosslinkage resulted from more functional oxetane groups.

In addition, from the transmittance data of examples 1-4, it can be concluded that, even without the presence of any antioxidants, the thermal curable composition disclosed in the present invention can achieve higher transparency than the radiation curable compositions disclosed in patent application WO 2012/045588 A1.

Comparison of example 1 (Ex. 1) and comparative example 1 (Comp. 1), proves that using the aromatic group containing bisphenol F diglycidyl ether (EXA-835LV) results in a higher water permeability than using an aliphatic epoxy resin. Moreover, the resulting film is less stable, showing yellowing after storage at 85° C./85RH for 10 days (transmittance lower than 80%). The WVTR data from comparative example 2 (Comp. 2), not using any oxetane compound, indicated that the desired very low water permeability cannot be achieved without adding an oxetane compound. Therefore, presence of an aliphatic oxetane is essential for achieving a good moisture barrier property.

The term “viscosity” as used throughout this specification refers to the viscosity as measured according to Brookfield, EN ISO 2555.

The term “molecular weight” (g/mol) as used throughout this specification stands for the number average molecular weight (Mn) as determined by GPC.

1-15. (canceled)

16. A curable composition, comprising:
a) an aliphatic epoxy compound,
b) an aliphatic oxetane compound,
c) a thermal cure initiator,
wherein the aliphatic epoxy compound is cycloaliphatic epoxy resin, and
wherein the aliphatic oxetane compound has the structure of 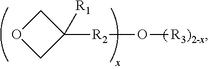
wherein R₁ is selected from the group consisting of hydrogen, C1 to C12 alkyl, C1 to C12 haloalkyl, C1 to C12 alkoxy and C1 to C12 alkyloyl groups; R₂ is selected from C1 to C12 alkylene groups; R₃ is selected from hydrogen, linear C1 to C12 alkyl, branched C3 to C12 alkyl and C5 to C12 cycloalkyl groups, and x is an integer from 1 to 2.

17. The curable composition according to claim 16, wherein the aliphatic oxetane compound contains 1 or 2 oxetane groups per molecule and is free of epoxy groups.

18. The curable composition according to claim 17, wherein the aliphatic oxetane compound has a molecular weight of less than 500 g/mol.

19. The curable composition according to claim 16, wherein the thermal cure initiator is selected from Brønsted acids, Lewis acids, and latent thermal acid generators.

20. The curable composition according to claim 16, wherein the composition after crosslinking has an initial transmittance of at least 85% at 400 nm wavelength.

21. The curable composition according to claim 16, wherein the curable composition further comprises one or more additives.

22. The curable composition according to claim 21, wherein the additives are selected from adhesion promoters, antioxidants, nanofillers, or rheology modifiers.

23. The curable composition according to claim 16, comprising:
a) from 35 to 97.9 wt-% of the aliphatic epoxy compound,
b) from 2 to 50 wt-% of the aliphatic oxetane compound,
c) from 0.1 to 5 wt-% of the thermal cure initiator,
d) from 0 to 10 wt-% of additives,
wherein the amount of components a) to d) sums to 100 wt-%.

24. A method of making an electronic device, comprising the steps:
providing a substrate having on one side at least an electronic circuit,
applying on such side a layer of a composition according to claim 16,
optionally bonding a second substrate on said layer,
curing the composition by heating up to a temperature of 80-120° C.

25. An electronic device comprising at least a substrate, a light emitting compound, and a layer of the cured composition according to claim 16, wherein the layer of the cured composition has an initial transmittance of at least 85% at 400 nm wavelength.

26. A method of making an organic light emitting diode (OLED) device comprising the steps:
providing a substrate having bound on one side one or more OLED stacks,
applying on the surface of the OLED stack(s) a layer of a composition according to claim 16,
optionally bonding a second substrate on said layer,
curing the composition by heating up to a temperature of 80-120° C.
